(19) United States
(12) Patent Application Publication
(10) Pub. No.: US 2026/0088250 A1
(43) Pub. Date: Mar. 26, 2026

(54) PLASMA PROCESSING APPARATUS

(71) Applicant: Tokyo Electron Limited, Tokyo (JP)

(72) Inventors: Naoki MATSUMOTO, Kurokawa-gun (JP); Shinya Ishikawa, Kurokawa-gun (JP)

(21) Appl. No.: 19/403,529

(22) Filed: Nov. 28, 2025

Related U.S. Application Data
(63) Continuation of application No. PCT/JP2024/007845, filed on Mar. 1, 2024.

(30) Foreign Application Priority Data
Jun. 5, 2023 (JP) 2023-092046

(51) Int. Cl. H01J 37/32

(52) U.S. Cl. CPC H01J 37/32146; H01J 37/32183; H01J 37/32541; H01J 37/32642; H01J 37/32724; H01J 2237/2007; H01J 2237/334

(57) ABSTRACT

A plasma processing apparatus includes a chamber; a substrate support disposed in the chamber, the substrate support including a conductive base, an electrostatic chuck, a substrate electrode electrically connected to the conductive base via a first conductor, a ring electrode electrically connected to the conductive base via a second conductor, and an edge ring disposed on the ring support surface to surround a substrate disposed on the substrate support surface; an RF generator electrically connected to the conductive base; a voltage pulse generator electrically connected to the conductive base; and a potential control circuit electrically connected to the second conductor between the ring electrode and the conductive base, the potential control circuit including at least one variable impedance element.

### CROSS-REFERENCE TO RELATED APPLICATIONS

This application is a bypass continuation application of international application No. PCT/JP2024/007845 having an international filing date of Mar. 1, 2024 and designating the United States, the international application being based upon and claiming the benefit of priority from Japanese Patent Application No. 2023-092046, filed on Jun. 5, 2023, the entire contents of which are incorporated herein by reference.

### BACKGROUND

### Field

An exemplary embodiment of the present disclosure relates to a plasma processing apparatus.

### Description of Related Art

JP2020-113752A discloses a technique for adjusting a plasma density in the vicinity of an edge of a substrate and a plasma density on a region of the substrate inside the edge in a plasma processing apparatus.

### SUMMARY

A plasma processing apparatus in one exemplary embodiment of the present disclosure includes: a chamber; a substrate support disposed in the chamber, the substrate support including a conductive base, an electrostatic chuck disposed on the conductive base and having a substrate support surface and a ring support surface, a substrate electrode disposed below the substrate support surface in the electrostatic chuck and electrically connected to the conductive base via a first conductor, a ring electrode disposed below the ring support surface in the electrostatic chuck and electrically connected to the conductive base via a second conductor, and an edge ring disposed on the ring support surface to surround a substrate disposed on the substrate support surface; an RF generator electrically connected to the conductive base and configured to generate an RF signal; a voltage pulse generator electrically connected to the conductive base and configured to generate a pulsed voltage signal; and a potential control circuit electrically connected to the second conductor between the ring electrode and the conductive base, the potential control circuit including at least one variable impedance element.

### BRIEF DESCRIPTION OF DRAWINGS

FIG. 1 is a diagram for describing a configuration example of a plasma processing system.

FIG. 2 is a diagram for describing a configuration example of the plasma processing apparatus.

FIG. 3 is a diagram for describing a configuration example of a substrate support and an electric circuit.

FIG. 4 is a diagram for describing a configuration example of a potential control circuit.

FIG. 5 is a diagram illustrating an example of control by a controller.

FIG. 6 is a diagram illustrating an example of an RF signal and a pulsed voltage signal in a first process.

FIG. 7 is a diagram illustrating another example of control by the controller.

FIG. 8 is a diagram illustrating an example of the RF signal and the pulsed voltage signal in a second process.

FIG. 9 is a diagram illustrating another example of control by the controller.

FIG. 10 is a diagram illustrating an example of the RF signal and the pulsed voltage signal in a third process.

FIG. 11 is a diagram for describing another configuration example of the substrate support and the electric circuit.

### DETAILED DESCRIPTION

Hereinafter, each embodiment of the present disclosure will be described.

In one exemplary embodiment, there is provided a plasma processing apparatus including: a chamber; a substrate support disposed in the chamber, the substrate support including a conductive base, an electrostatic chuck disposed on the conductive base and having a substrate support surface and a ring support surface, a substrate electrode disposed below the substrate support surface in the electrostatic chuck and electrically connected to the conductive base via a first conductor, a ring electrode disposed below the ring support surface in the electrostatic chuck and electrically connected to the conductive base via a second conductor, and an edge ring disposed on the ring support surface to surround a substrate disposed on the substrate support surface; an RF generator electrically connected to the conductive base and configured to generate an RF signal; a voltage pulse generator electrically connected to the conductive base and configured to generate a pulsed voltage signal; and a potential control circuit electrically connected to the second conductor between the ring electrode and the conductive base, the potential control circuit including at least one variable impedance element.

In one exemplary embodiment the substrate support is configured such that a height of an upper surface of the edge ring is higher than a height of an upper surface of the substrate disposed on the substrate support surface.

In one exemplary embodiment, the substrate support includes at least one substrate chuck electrode, and the at least one substrate chuck electrode is disposed between the substrate electrode and the substrate support surface in the electrostatic chuck.

In one exemplary embodiment, the substrate support includes at least one ring chuck electrode, and the at least one ring chuck electrode is disposed between the ring electrode and the ring support surface in the electrostatic chuck.

In one exemplary embodiment, the substrate support includes at least one substrate heating element, and the at least one substrate heating element is disposed below the substrate electrode in the electrostatic chuck.

In one exemplary embodiment, the at least one substrate heating element includes a plurality of substrate heating elements arranged in a horizontal direction.

In one exemplary embodiment, the substrate support includes at least one ring heating element, and the at least one ring heating element is disposed below the ring electrode in the electrostatic chuck.

In one exemplary embodiment, the at least one ring heating element includes a plurality of ring heating elements arranged in a horizontal direction.

In one exemplary embodiment, the plasma processing apparatus further includes: an RF filter electrically connected between the voltage pulse generator and the conductive base; and a voltage pulse filter electrically connected between the RF generator and the conductive base.

In one exemplary embodiment, the plasma processing apparatus further includes a controller configured to adjust the at least one variable impedance element based on a consumption amount of the edge ring.

In one exemplary embodiment, the consumption amount of the edge ring is determined based on an operation time of the RF generator.

In one exemplary embodiment, the at least one variable impedance element includes first and second variable capacitors connected to each other in parallel, the first variable capacitor is configured to control the RF signal supplied to the ring electrode, and the second variable capacitor is configured to control the pulsed voltage signal applied to the ring electrode.

In one exemplary embodiment, the potential control circuit includes a filter connected in parallel with the second variable capacitor.

In one exemplary embodiment, the plasma processing apparatus further includes a controller, in which the controller is configured to execute (a) adjusting the first variable capacitor, and (b) executing a first process after the (a), and in the (b), the RF signal has a first power level higher than a zero power level, and the pulsed voltage signal has a zero voltage level.

In one exemplary embodiment, the controller is configured to execute (c) adjusting the second variable capacitor, and (d) executing a second process after the (c), and in the (d), the RF signal has the zero power level, and the pulsed voltage signal has a first voltage level higher than the zero voltage level.

In one exemplary embodiment, the first voltage level has a negative polarity.

In one exemplary embodiment, the controller is configured to execute (e) adjusting the second variable capacitor, and (f) executing a third process after the (e), and in the (f), the RF signal has the first power level or a second power level different from the first power level, and the pulsed voltage signal has the first voltage level or a second voltage level different from the first voltage level.

In one exemplary embodiment, there is provided a plasma processing apparatus including: a chamber; a substrate support disposed in the chamber, the substrate support including a conductive base, an electrostatic chuck disposed on the conductive base and having a substrate support surface and a ring support surface, a substrate electrode disposed below the substrate support surface in the electrostatic chuck and electrically connected to the conductive base via a first conductor, a ring electrode disposed below the ring support surface in the electrostatic chuck and electrically connected to the conductive base via a second conductor, and an edge ring disposed on the ring support surface to surround a substrate disposed on the substrate support surface; at least one power supply electrically connected to the conductive base; and a potential control circuit electrically connected to the second conductor between the ring electrode and the conductive base, the potential control circuit including at least one variable impedance element.

Hereinafter, each embodiment of the present disclosure will be described in detail with reference to the drawings. In each drawing, the same or similar elements will be given the same reference numerals, and repeated descriptions will be omitted. Unless otherwise specified, a positional relationship such as up, down, left, and right will be described based on a positional relationship illustrated in the drawings. A dimensional ratio in the drawings does not indicate an actual ratio, and the actual ratio is not limited to the ratio illustrated in the drawings.

### Example of Plasma Processing System

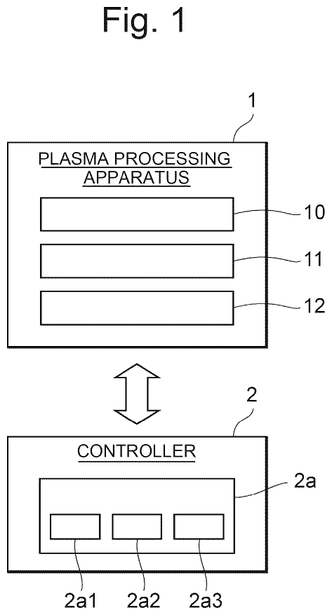

FIG. 1 is a diagram for describing a configuration example of a plasma processing system. In an embodiment, the plasma processing system includes a plasma processing apparatus 1 and a controller 2. The plasma processing system is an example of a substrate processing system, and the plasma processing apparatus 1 is an example of a substrate processing apparatus. The plasma processing apparatus 1 includes a plasma processing chamber 10, a substrate support 11, and a plasma generator 12. The plasma processing chamber 10 has a plasma processing space. In addition, the plasma processing chamber 10 has at least one gas supply port for supplying at least one processing gas to the plasma processing space and at least one gas exhaust port for exhausting the gas from the plasma processing space. The gas supply port is connected to a gas supply 20 which is described later, and the gas exhaust port is connected to an exhaust system 40 which is described later. The substrate support 11 is disposed in the plasma processing space and has a substrate support surface for supporting a substrate.

The plasma generator 12 is configured to form a plasma from at least one processing gas supplied into the plasma processing space. The plasma formed in the plasma processing space may be a capacitively coupled plasma (CCP), an inductively coupled plasma (ICP), an electron-cyclotron-resonance plasma (ECR plasma), a helicon wave plasma (HWP), a surface wave plasma (SWP), or the like. Further, various types of plasma generators including an alternating current (AC) plasma generator and a direct current (DC) plasma generator may be used. In an embodiment, an AC signal (AC power) used in the AC plasma generator has a frequency in the range of 100 kHz to 10 GHz. Therefore, the AC signal includes a radio frequency (RF) signal and a microwave signal. In an embodiment, the RF signal has a frequency in the range of 100 kHz to 150 MHz.

The controller 2 processes a computer-executable instruction that causes the plasma processing apparatus 1 to execute various steps described in the present disclosure. The controller 2 may be configured to control each element of the plasma processing apparatus 1 to execute the various steps described here. In an embodiment, a part or all of the controller 2 may be included in the plasma processing apparatus 1. The controller 2 may include a processor 2a1, a storage 2a2, and a communication interface 2a3. The controller 2 is realized by, for example, a computer 2a. The processor 2a1 may be configured to read out a program from the storage 2a2 and to execute the read-out program to perform various control operations. This program may be stored in the storage 2a2 in advance, or may be acquired via a medium when necessary. The acquired program is stored in the storage 2a2, is read out from the storage 2a2, and executed by the processor 2a1. The medium may be various storage media readable by the computer 2a or may be a communication line connected to the communication interface 2a3. The processor 2a1 may be a central processing unit (CPU). The storage 2a2 may include a random access memory (RAM), a read only memory (ROM), a hard disk drive (HDD), a solid state drive (SSD), or a combination thereof. The communication interface 2a3 may communicate with the plasma processing apparatus 1 via a communication line such as a local area network (LAN).

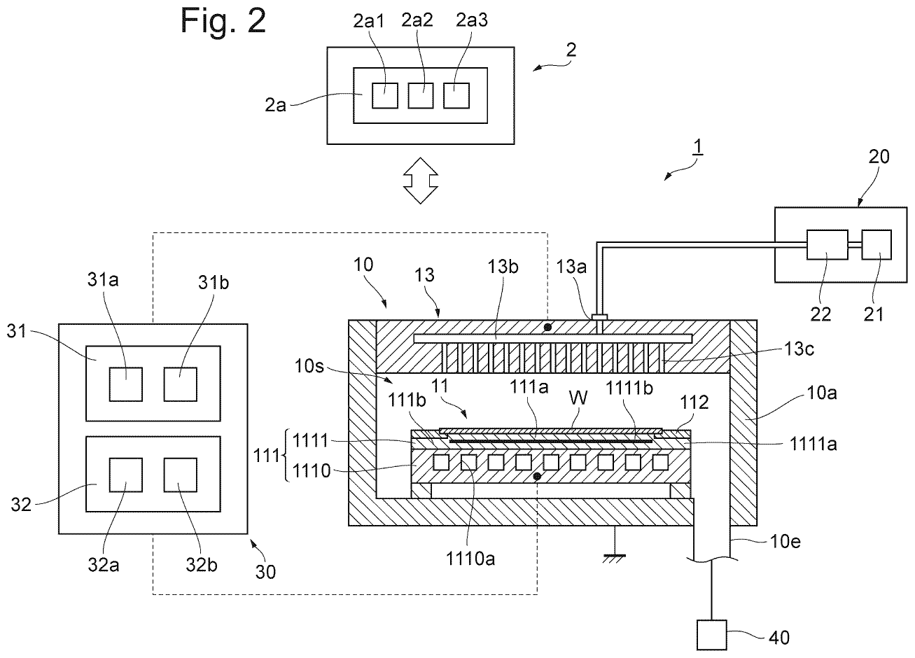

Hereinafter, a configuration example of a capacitively coupled plasma processing apparatus as an example of the plasma processing apparatus 1 will be described. FIG. 2 is a diagram for describing a configuration example of the capacitively coupled plasma processing apparatus 1.

The capacitively coupled plasma processing apparatus 1 includes a plasma processing chamber 10 (also simply referred to as a “chamber”), a gas supply 20, a power supply 30, and an exhaust system 40. In addition, the plasma processing apparatus 1 includes a substrate support 11 and a gas introducer. The gas introducer is configured to introduce at least one processing gas into the plasma processing chamber 10. The gas introducer includes a shower head 13. The substrate support 11 is disposed in the plasma processing chamber 10. The shower head 13 is disposed above the substrate support 11. In an embodiment, the shower head 13 configures at least a part of a ceiling of the plasma processing chamber 10. The plasma processing chamber 10 has a plasma processing space 10s defined by the shower head 13, a side wall 10a of the plasma processing chamber 10, and the substrate support 11. The plasma processing chamber 10 is grounded. The shower head 13 and the substrate support 11 are electrically insulated from a housing of the plasma processing chamber 10.

The substrate support 11 includes a main body 111 and a ring assembly 112. The main body 111 has a center region 111a for supporting a substrate W and an annular region 111b for supporting the ring assembly 112. A wafer is an example of the substrate W. The annular region 111b of the main body 111 surrounds the center region 111a of the main body 111 in plan view. The substrate W is disposed on the center region 111a of the main body 111, and the ring assembly 112 is disposed on the annular region 111b of the main body 111 to surround the substrate W on the center region 111a of the main body 111. Therefore, the center region 111a is also referred to as a substrate support surface for supporting the substrate W, and the annular region 111b is also referred to as a ring support surface for supporting the ring assembly 112.

In an embodiment, the main body 111 includes a base 1110 (also referred to as a “conductive base”) and an electrostatic chuck 1111. The base 1110 includes a conductive member. The conductive member of the base 1110 may function as a lower electrode. The electrostatic chuck 1111 is disposed on the base 1110. The electrostatic chuck 1111 includes a ceramic member 1111a and an electrostatic electrode 1111b disposed in the ceramic member 1111a. The ceramic member 1111a has the center region 111a. In an embodiment, the ceramic member 1111a also has the annular region 111b. Another member that surrounds the electrostatic chuck 1111 may have the annular region 111b, such as an annular electrostatic chuck or an annular insulating member. In this case, the ring assembly 112 may be disposed on the annular electrostatic chuck or the annular insulating member, or may be disposed on both the electrostatic chuck 1111 and the annular insulating member. Further, at least one RF/DC electrode coupled to an RF power supply 31 and/or a DC power supply 32, which will be described later, may be disposed in the ceramic member 1111a. In this case, at least one RF/DC electrode functions as the lower electrode. When a bias RF signal and/or a DC signal, which will be described later, are supplied to at least one RF/DC electrode, the RF/DC electrode is also referred to as a bias electrode. The conductive member of the base 1110 and at least one RF/DC electrode may function as a plurality of lower electrodes. Further, the electrostatic electrode 1111b may function as the lower electrode. Therefore, the substrate support 11 includes at least one lower electrode.

The ring assembly 112 includes one or a plurality of annular members. In an embodiment, one or the plurality of annular members includes one or a plurality of edge rings and at least one cover ring. The edge ring is formed of a conductive material or an insulating material, and the cover ring is formed of an insulating material.

In addition, the substrate support 11 may include a temperature-controlled module configured to adjust at least one of the electrostatic chuck 1111, the ring assembly 112, and the substrate to a target temperature. The temperature-controlled module may include a heater, a heat transfer medium, a flow passage 1110a, or a combination thereof. A heat transfer fluid such as brine or a gas flows in the flow passage 1110a. In an embodiment, the flow passage 1110a is formed in the base 1110, and one or a plurality of heaters is disposed in the ceramic member 1111a of the electrostatic chuck 1111. Further, the substrate support 11 may include a heat transfer gas supply configured to supply the heat transfer gas to a gap between a back surface of the substrate W and the center region 111a.

The shower head 13 is configured to introduce at least one processing gas into the plasma processing space 10s from the gas supply 20. The shower head 13 has at least one gas supply port 13a, at least one gas diffusion chamber 13b, and a plurality of gas introduction ports 13c. The processing gas supplied to the gas supply port 13a passes through the gas diffusion chamber 13b and is introduced into the plasma processing space 10s from the plurality of gas introduction ports 13c. In addition, the shower head 13 includes at least one upper electrode. In addition to the shower head 13, the gas introducer may include one or a plurality of side gas injectors (SGI) attached to one or a plurality of opening portions formed on the side wall 10a.

The gas supply 20 may include at least one gas source 21 and at least one flow rate controller 22. In an embodiment, the gas supply 20 is configured to supply at least one processing gas to the shower head 13 from each corresponding gas source 21 via each corresponding flow rate controller 22. Each flow rate controller 22 may include, for example, a mass flow controller or a pressure-controlled flow rate controller. Further, the gas supply 20 may include at least one flow rate modulation device that modulates or pulses a flow rate of at least one processing gas.

The power supply 30 includes the RF power supply 31 coupled to the plasma processing chamber 10 via at least one impedance matching circuit. The RF power supply 31 is configured to supply at least one RF signal (RF power) to at least one lower electrode and/or at least one upper electrode. As a result, the plasma is formed from at least one processing gas supplied to the plasma processing space 10s. Therefore, the RF power supply 31 may function as at least a part of the plasma generator 12. Further, by supplying the bias RF signal to at least one lower electrode, a bias potential is generated in the substrate W, and an ion component in the formed plasma is able to be drawn into the substrate W.

In an embodiment, the RF power supply 31 includes a first RF generator 31a and a second RF generator 31b. The first RF generator 31a is coupled to at least one lower electrode and/or at least one upper electrode via at least one impedance matching circuit and is configured to generate a source RF signal (source RF power) for plasma formation. In an embodiment, the source RF signal has a frequency in the range of 10 MHz to 150 MHz. In an embodiment, the first RF generator 31a may be configured to generate a plurality of source RF signals having different frequencies. The generated one or plurality of source RF signals is supplied to at least one lower electrode and/or at least one upper electrode.

The second RF generator 31b is coupled to at least one lower electrode via at least one impedance matching circuit and is configured to generate the bias RF signal (bias RF power). The frequency of the bias RF signal may be the same as or different from the frequency of the source RF signal. In an embodiment, the bias RF signal has a frequency lower than the frequency of the source RF signal. In an embodiment, the bias RF signal has a frequency in the range of 100 kHz to 60 MHz. In an embodiment, the second RF generator 31b may be configured to generate a plurality of bias RF signals having different frequencies. The generated one or plurality of bias RF signals is supplied to at least one lower electrode. In addition, in various embodiments, at least one of the source RF signal and the bias RF signal may be pulsed.

In addition, the power supply 30 may include the DC power supply 32 coupled to the plasma processing chamber 10. The DC power supply 32 includes the first DC generator 32a and the second DC generator 32b. In an embodiment, the first DC generator 32a is connected to at least one lower electrode, and is configured to generate the first DC signal. The generated first DC signal is applied to at least one lower electrode. In an embodiment, the second DC generator 32b is connected to at least one upper electrode and is configured to generate a second DC signal. The generated second DC signal is applied to at least one upper electrode.

In various embodiments, the first and second DC signals may be pulsed. In this case, a sequence of voltage pulses is applied to at least one lower electrode and/or at least one upper electrode. The voltage pulse may have a pulse waveform having a rectangular shape, a trapezoidal shape, a triangular shape, or a combination thereof. In an embodiment, a waveform generator for generating the sequence of voltage pulses from the DC signal is connected between the first DC generator 32a and at least one lower electrode. Therefore, the first DC generator 32a and the waveform generator configure the voltage pulse generator. When the second DC generator 32b and the waveform generator configure the voltage pulse generator, the voltage pulse generator is connected to at least one upper electrode. The voltage pulse may have a positive polarity or a negative polarity. In addition, the sequence of voltage pulses may include one or a plurality of voltage pulses of the positive polarity and one or a plurality of voltage pulses of the negative polarity in one cycle. The first and second DC generators 32a and 32b may be provided in addition to the RF power supply 31, or the first DC generator 32a may be provided instead of the second RF generator 31b.

The exhaust system 40 may be connected to, for example, a gas exhaust port 10e provided at a bottom portion of the plasma processing chamber 10. The exhaust system 40 may include a pressure regulating valve and a vacuum pump. A pressure in the plasma processing space 10s is regulated by the pressure regulating valve. The vacuum pump may include a turbo molecular pump, a dry pump, or a combination thereof.

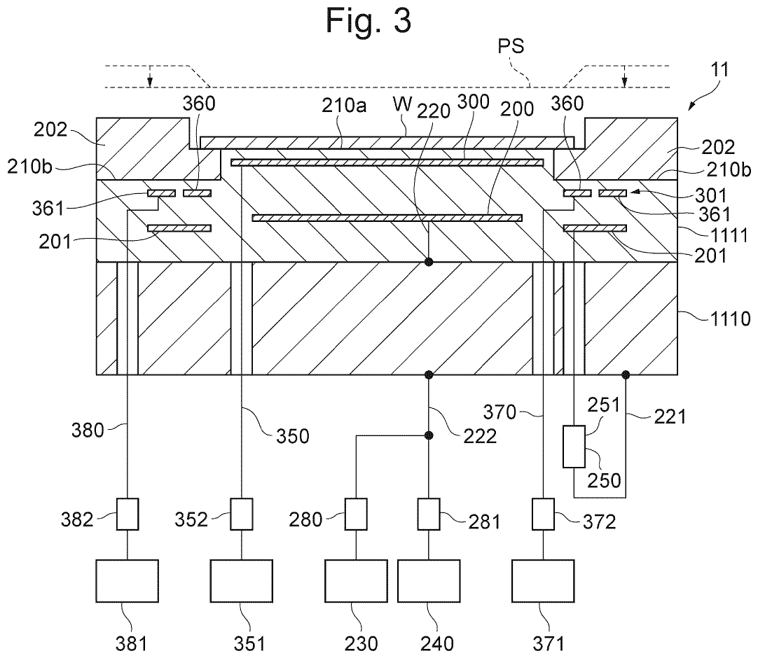

FIG. 3 is a diagram for describing a configuration example of the substrate support 11 and the electric circuit in an embodiment. In an embodiment, the substrate support 11 may include the conductive base 1110, the electrostatic chuck 1111, a substrate electrode 200, a ring electrode 201, and an edge ring 202.

In an embodiment, the electrostatic chuck 1111 may include a substrate support surface 210a and a ring support surface 210b disposed to surround the substrate support surface 210a on an upper surface thereof. The substrate support surface 210a may be an example of the center region 111a illustrated in FIG. 2. The ring support surface 210b may be an example of the annular region 111b illustrated in FIG. 2.

As illustrated in FIG. 3, the substrate electrode 200 may be disposed in the electrostatic chuck 1111. The substrate electrode 200 may be disposed below the substrate support surface 210a. The substrate electrode 200 may be electrically connected to the conductive base 1110 via the first conductor 220. The substrate electrode 200 may have a circular shape. The substrate electrode 200 may be disposed such that the center of the substrate electrode 200 coincides with the center of the electrostatic chuck 1111 in plan view.

As illustrated in FIG. 3, the ring electrode 201 may be disposed in the electrostatic chuck 1111. The ring electrode 201 may be disposed below the ring support surface 210b. The ring electrode 201 may be electrically connected to the conductive base 1110 via the second conductor 221. The ring electrode 201 may have an annular shape. The ring electrode 201 may be disposed such that the center of the ring electrode 201 coincides with the center of the electrostatic chuck 1111 in plan view.

The edge ring 202 may be disposed on the ring support surface 210b to surround the substrate W disposed on the substrate support surface 210a. The edge ring 202 may be configured such that a height of the upper surface is larger than a height of the upper surface of the substrate W disposed on the substrate support surface 210a. The thickness of the edge ring 202 in the vertical direction may be set to a thickness at which the substrate W and a plasma sheath PS on the edge ring 202 are horizontal when the capacitances of variable capacitors 270 and 271 described later are set to be maximum (the impedance is set to be minimum). The edge ring 202 may be included in the ring assembly 112 illustrated in FIG. 2.

As illustrated in FIG. 3, the conductive base 1110 may be electrically connected to the RF generator 230 via a third conductor 222. The RF generator 230 may be configured to generate the RF signal. The RF generator 230 may be configured to generate the bias RF signal. The frequency of the bias RF signal may have a frequency in the range of 100 kHz to 60 MHz. The RF generator 230 may be configured to generate the source RF signal for plasma formation. The source RF signal may have a frequency in the range of 10 MHz to 150 MHz. The RF generator 230 may be an example of the second RF generator 31b illustrated in FIG. 2.

As illustrated in FIG. 3, the conductive base 1110 may be electrically connected to a voltage pulse generator 240 via the third conductor 222. The voltage pulse generator 240 may be configured to generate a pulsed voltage signal. The voltage pulse generator 240 may be an example of the first DC generator 32a illustrated in FIG. 2.

The substrate electrode 200 illustrated in FIG. 3 may be electrically connected to the RF generator 230 and the voltage pulse generator 240 via the first conductor 220, the conductive base 1110, and the third conductor 222. The ring electrode 201 may be electrically connected to the RF generator 230 and the voltage pulse generator 240 via the second conductor 221, the conductive base 1110, and the third conductor 222.

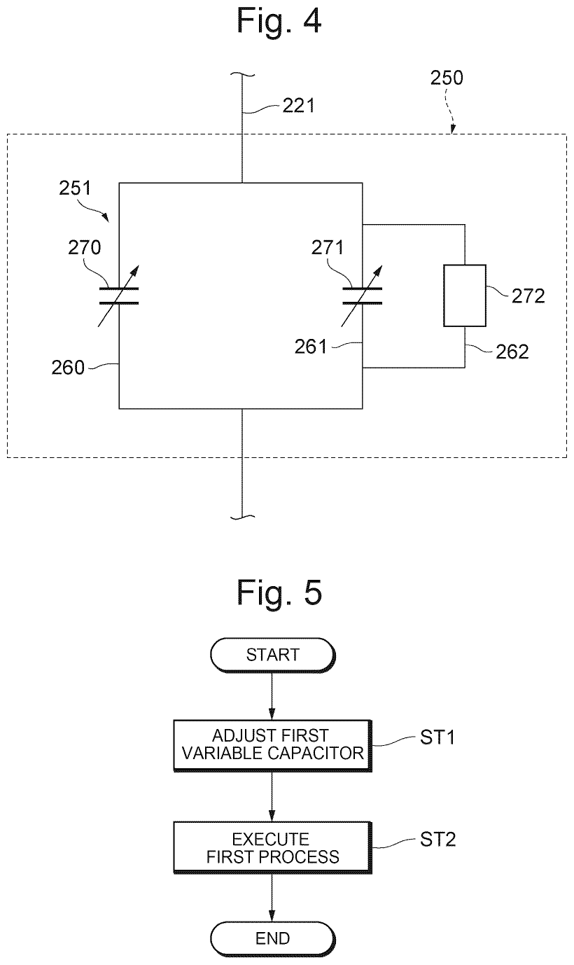

A potential control circuit 250 may be electrically connected to the second conductor 221 between the ring electrode 201 and the conductive base 1110. The potential control circuit 250 may include at least one variable impedance element 251. In an embodiment, as illustrated in FIG. 4, the variable impedance element 251 may include a first variable capacitor 270 and a second variable capacitor 271. The potential control circuit 250 may include a first circuit conductor 260 and a second circuit conductor 261 connected in parallel. The first variable capacitor 270 may be disposed on the first circuit conductor 260, and the second variable capacitor 271 may be disposed on the second circuit conductor 261.

The first variable capacitor 270 and the second variable capacitor 271 may be configured to be capable of varying an electric capacitance. The first variable capacitor 270 may be configured to control the RF signal supplied to the ring electrode 201 by changing the electric capacitance to adjust the impedance. The second variable capacitor may be configured to control the pulsed voltage signal applied to the ring electrode 201 by changing the electric capacitance to adjust the impedance. The second variable capacitor 271 may be configured to vary the electric capacitance in a range of a relatively high electric capacitance as compared with the first variable capacitor 270.

The potential control circuit 250 may include a third circuit conductor 262 connected in parallel with the second circuit conductor 261. A filter 272 may be disposed in the third circuit conductor 262. The filter 272 may include a coil. The filter 272 may be configured to resonate with the second variable capacitor 271 when a high RF signal is input, and to increase the impedance of the second circuit conductor 261 and the third circuit conductor 262. In addition, the filter 272 may be configured not to resonate with the second variable capacitor 271 when a low RF pulsed voltage signal is input, and to allow the pulsed voltage signal to pass through the second circuit conductor 261. As a result, the high RF signal may mainly pass through the first circuit conductor 260, and the low RF pulsed voltage signal may mainly pass through the second circuit conductor 261. The electric capacitance (impedance) of the first variable capacitor 270 and the second variable capacitor 271 may be adjusted by the controller 2.

As illustrated in FIG. 3, a voltage pulse filter 280 may be electrically connected to the third conductor 222 between the RF generator 230 and the conductive base 1110. The voltage pulse filter 280 may be configured to suppress the pulsed voltage signal supplied from the voltage pulse generator 240 from entering the RF generator 230 via the third conductor 222.

An RF filter 281 may be electrically connected to the third conductor 222 between the voltage pulse generator 240 and the conductive base 1110. The RF filter 281 may be configured to suppress the RF signal supplied from the RF generator 230 from entering the voltage pulse generator 240 via the third conductor 222.

In an embodiment, the substrate support 11 may further include at least one substrate chuck electrode 300 and at least one ring chuck electrode 301.

The substrate chuck electrode 300 may be disposed at least one between the substrate support surface 210a and the substrate electrode 200 in the electrostatic chuck 1111. The substrate chuck electrode 300 may be electrically connected to a direct current power supply 351 via a fourth conductor 350. The fourth conductor 350 may be electrically connected to at least one filter 352 of the RF filter and the voltage pulse filter. The fourth conductor 350 may be electrically insulated from the conductive base 1110. When a direct current voltage from the direct current power supply 351 is applied to the substrate chuck electrode 300, an electrostatic attraction force (Coulomb force) is generated between the substrate chuck electrode 300 and the substrate W. The substrate W may be attracted by the electrostatic attraction force thereof to the electrostatic chuck 1111 and adsorbed and held on the substrate support surface 210a. The substrate chuck electrode 300 may include a plurality of substrate chuck electrodes. The substrate chuck electrode 300 may be an example of the electrostatic electrode 1111b illustrated in FIG. 2.

As illustrated in FIG. 3, the ring chuck electrode 301 may be disposed at least one between the ring support surface 210b and the ring electrode 201 in the electrostatic chuck 1111. The ring chuck electrode 301 may include an inner chuck electrode 360 and an outer chuck electrode 361.

The inner chuck electrode 360 and the outer chuck electrode 361 may have an annular shape. The inner chuck electrode 360 and the outer chuck electrode 361 may be disposed such that centers thereof coincide with each other in plan view. The inner chuck electrode 360 and the outer chuck electrode 361 may be disposed at the same position in the vertical direction.

The inner chuck electrode 360 may be electrically connected to a direct current power supply 371 via a fifth conductor 370. The outer chuck electrode 361 may be electrically connected to a direct current power supply 381 via a sixth conductor 380. The ring chuck electrode 301 may set a potential difference between the inner chuck electrode 360 and the outer chuck electrode 361, and the edge ring 202 may be adsorbed and held on the ring support surface 210b by the potential difference. The fifth conductor 370 and the sixth conductor 380 may be electrically connected to at least one of the filter 372 and 382 in the RF filter and the voltage pulse filter. The fifth conductor 370 and the sixth conductor 380 may be electrically insulated from the conductive base 1110. The ring chuck electrode 301 may include one chuck electrode or may include three or more chuck electrodes.

### Example of Plasma Processing Method

In an embodiment, the plasma processing method includes etching processing of etching a film on the substrate W using the plasma. In an embodiment, the plasma processing method is executed by the controller 2 in the plasma processing apparatus 1.

First, the substrate W is transported into the chamber 10 by a transport arm, placed on the substrate support 11 by a lifter, and is adsorbed and held on the substrate support 11 as illustrated in FIG. 2.

Next, the processing gas is supplied to the shower head 13 by the gas supply 20, and is supplied from the shower head 13 to the plasma processing space 10s. The processing gas supplied at this time includes a gas that generates an active species required for the etching processing of the substrate W.

The source RF signal is supplied from the RF power supply 31 to the upper electrode or the lower electrode. In addition, the bias RF signal or the pulsed voltage signal is supplied to the lower electrode from the RF power supply 31 or the DC power supply 32. The atmosphere in the plasma processing space 10s is exhausted from the gas exhaust port 10e, and the inside of the plasma processing space 10s is depressurized. As a result, the plasma is formed from the processing gas on the substrate support 11 of the plasma processing space 10s, and the substrate W is subjected to the etching processing.

In the above-described etching processing, the following control may be executed by the controller 2. FIG. 5 is a flowchart describing an example of control performed by the controller 2. The control illustrated in FIG. 5 may be a case where the RF signal is supplied to the substrate electrode 200 and the ring electrode 201. The controller 2 may execute step ST1 of adjusting the first variable capacitor 270 and step ST2 of executing a first process after step ST1.

In step ST1, the electric capacitance of the first variable capacitor 270 may be adjusted, and the impedance of the potential control circuit 250 may be adjusted. In step ST2 described later, the electric capacitance of the first variable capacitor 270 may be adjusted such that the potential of the edge ring 202 is a potential at which the plasma sheath PS generated on the substrate W and the edge ring 202 is close to a horizontal. The adjustment of the electric capacitance of the first variable capacitor 270 may be performed based on a consumption amount of the edge ring 202. In addition, the consumption amount of the edge ring 202 may be determined based on an integrated time during which the RF signal is supplied from the RF generator 230 to the conductive base 1110, that is, an operation time of the RF generator 230. The consumption amount of the edge ring 202 may be detected by a sensor or the like. As the consumption amount of the edge ring 202 increases, the electric capacitance of the first variable capacitor 270 may be increased. Step ST1 may be performed before the plasma is formed.

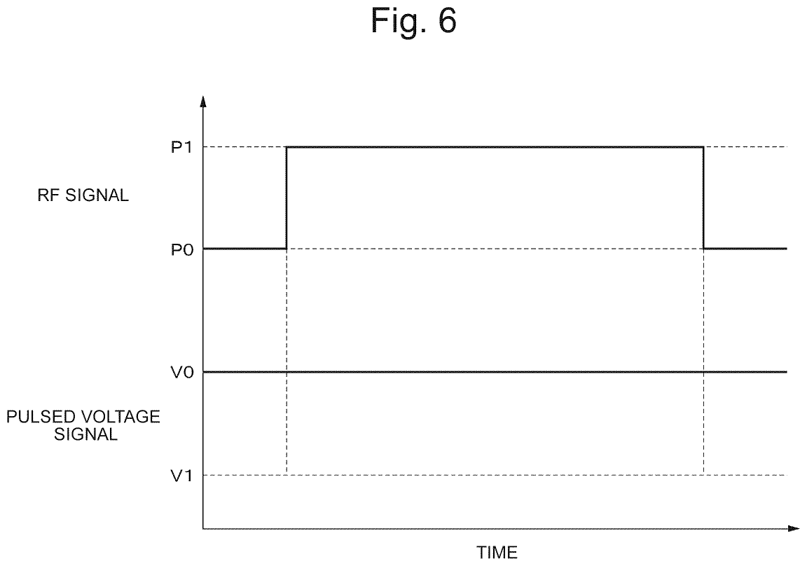

In step ST2, the RF signal may be supplied from the RF generator 230 to the conductive base 1110 during the plasma formation. The RF signal may be the bias RF signal. As illustrated in FIG. 6, the RF signal may have a first power level P1 higher than a zero power level P0 (the RF signal is ON). In this case, the pulsed voltage signal supplied from the voltage pulse generator 240 to the conductive base 1110 may have a zero voltage level V0 (the pulsed voltage signal is OFF). The RF signal may be supplied from the RF generator 230 illustrated in FIG. 3 to the substrate electrode 200 via the third conductor 222, the conductive base 1110, and the first conductor 220. The RF signal may be supplied from the RF generator 230 to the ring electrode 201 via the third conductor 222, the conductive base 1110, and the second conductor 221. In the potential control circuit 250 of the second conductor 221 illustrated in FIG. 5, the RF signal may mainly pass through the first variable capacitor 270. In this case, the potentials of the ring electrode 201 and the edge ring 202 may be defined by the impedance defined by the first variable capacitor 270. The RF signal may cause the resonance in the second variable capacitor 271 and the filter 272, and the impedance is increased, so that the flow to the second variable capacitor 271 may be suppressed. In this way, the potentials of the ring electrode 201 and the edge ring 202 are adjusted with respect to the potentials of the substrate electrode 200 and the substrate W illustrated in FIG. 3, and the plasma sheaths PS generated on the substrate W and the edge ring 202 may be brought close to the horizontal. As a result, ions of the plasma may be supplied perpendicularly to the substrate W in the vicinity of an outer peripheral portion of the substrate W. Therefore, a state where a tilt angle (incidence angle of the ion with respect to the substrate W) is 90° may be maintained.

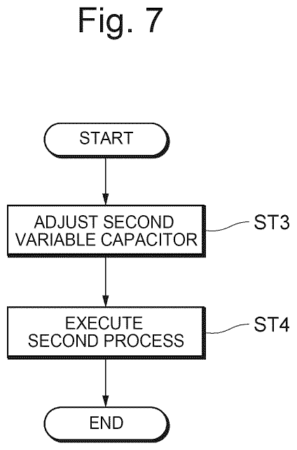

FIG. 7 is a flowchart describing another example of the control by the controller 2. The control illustrated in FIG. 7 may be a case where the pulsed voltage signal is supplied to the substrate electrode 200 and the ring electrode 201. The controller 2 may execute step ST3 of adjusting the second variable capacitor 271 and step ST4 of executing the second process after step ST3.

In step ST3, the electric capacitance of the second variable capacitor 271 may be adjusted, and the impedance of the potential control circuit 250 may be adjusted. In step ST4 described later, the electric capacitance of the second variable capacitor 271 may be adjusted such that the potentials of the ring electrode 201 and the edge ring 202 are potentials at which the plasma sheaths PS generated on the substrate W and the edge ring 202 are close to the horizontal. The adjustment of the electric capacitance of the second variable capacitor 271 may be performed based on the consumption amount of the edge ring 202. In addition, the consumption amount of the edge ring 202 may be determined based on the integrated time (operation time of the voltage pulse generator 240) in which the pulsed voltage signal is supplied from the voltage pulse generator 240 to the conductive base 1110. The consumption amount of the edge ring 202 may be detected by a sensor or the like. As the consumption amount of the edge ring 202 increases, the electric capacitance of the second variable capacitor 271 may be increased. Step ST3 may be performed before the plasma is formed.

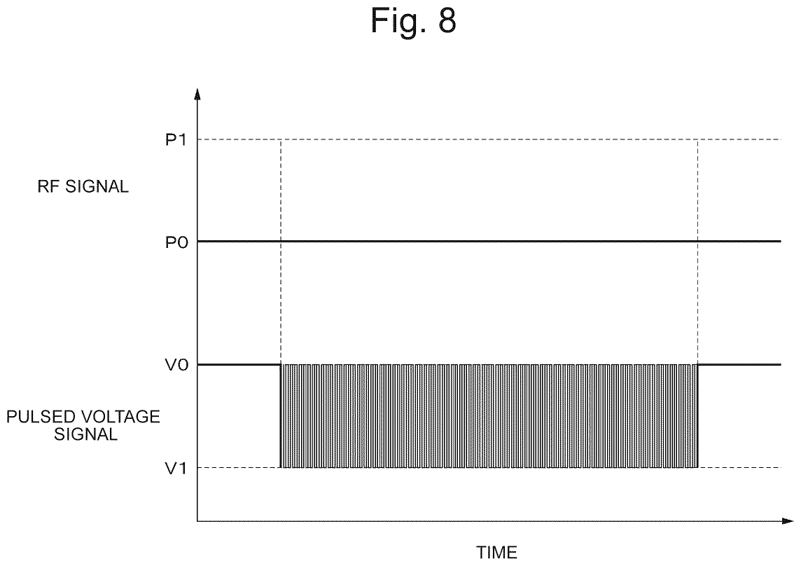

In step ST4, the pulsed voltage signal may be supplied from the voltage pulse generator 240 to the conductive base 1110 during the plasma formation. As illustrated in FIG. 8, the pulsed voltage signal may have a first voltage level V1 higher than the zero voltage level V0 (the pulsed voltage signal is ON). The first voltage level V1 may have a negative polarity. In this case, the RF signal supplied from the RF generator 230 to the conductive base 1110 may have the zero power level P0 (the RF signal is OFF). The pulsed voltage signal may be supplied from the voltage pulse generator 240 illustrated in FIG. 3 to the substrate electrode 200 via the third conductor 222, the conductive base 1110, and the first conductor 220. The pulsed voltage signal may be supplied from the voltage pulse generator 240 to the ring electrode 201 via the third conductor 222, the conductive base 1110, and the second conductor 221. The pulsed voltage signal may mainly pass through the second variable capacitor 271 in the potential control circuit 250 of the second conductor 221 illustrated in FIG. 5. In this case, the potentials of the ring electrode 201 and the edge ring 202 may be defined by the impedance defined by the second variable capacitor 271. In the first variable capacitor 270 having a relatively low electric capacitance, the impedance of the pulsed voltage signal is high, and the flow of the pulsed voltage signal to the first variable capacitor 270 may be suppressed. In this way, the potentials of the ring electrode 201 and the edge ring 202 are adjusted with respect to the potentials of the substrate electrode 200 and the substrate W illustrated in FIG. 3, and the plasma sheaths PS generated on the substrate W and the edge ring 202 may be brought close to the horizontal. As a result, ions of the plasma may be supplied perpendicularly to the substrate W in the vicinity of an outer peripheral portion of the substrate W. Therefore, a state where a tilt angle (incidence angle of the ion with respect to the substrate W) is 90° may be maintained.

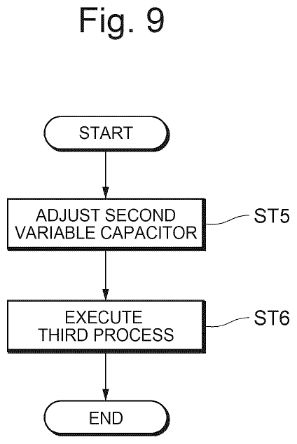

FIG. 9 is a flowchart describing another example of the control by the controller 2. The control illustrated in FIG. 9 may be a case where the RF signal and the pulsed voltage signal are supplied to the substrate electrode 200 and the ring electrode 201. The controller 2 may execute step ST5 of adjusting the second variable capacitor 271 and step ST6 of executing the third process after step ST5.

In step ST5, the electric capacitance of the second variable capacitor 271 may be adjusted, and the impedance of the potential control circuit 250 may be adjusted. In step ST6 described later, the electric capacitance of the second variable capacitor 271 may be adjusted such that the potentials of the ring electrode 201 and the edge ring 202 are potentials at which the plasma sheaths PS generated on the substrate W and the edge ring 202 are close to the horizontal. The adjustment of the electric capacitance of the second variable capacitor 271 may be performed based on the consumption amount of the edge ring 202. In addition, the consumption amount of the edge ring 202 may be determined based on the integrated time (operation time of the voltage pulse generator 240) in which the pulsed voltage signal is supplied from the voltage pulse generator 240 to the conductive base 1110. The consumption amount of the edge ring 202 may be detected by a sensor or the like. As the consumption amount of the edge ring 202 increases, the electric capacitance of the second variable capacitor 271 may be increased. Step ST3 may be performed before the plasma is formed.

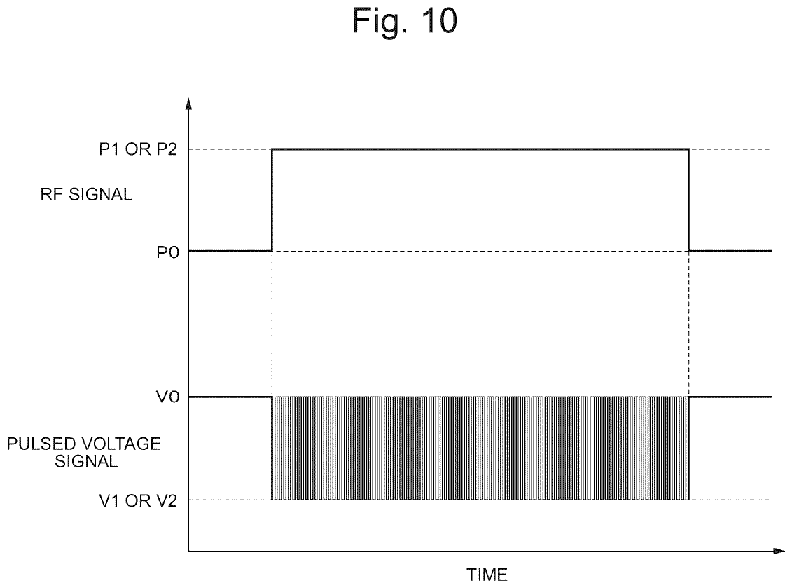

In step ST6, during the plasma formation, the RF signal may be supplied from the RF generator 230 to the conductive base 1110, and the pulsed voltage signal may be supplied from the voltage pulse generator 240 to the conductive base 1110. As illustrated in FIG. 10, the RF signal may have the first power level P1 that is higher than the zero power level or the second power level P2 different from the first power level P1 (the RF signal is ON). The pulsed voltage signal may have the first voltage level V1 or the second voltage level V2 different from the first voltage level V1 (the pulsed voltage signal is ON). The RF signal and the pulsed voltage signal may be supplied to the substrate electrode 200 via the third conductor 222, the conductive base 1110, and the first conductor 220 illustrated in FIG. 3. The RF signal and the pulsed voltage signal may be supplied to the ring electrode 201 via the third conductor 222, the conductive base 1110, and the second conductor 221. In the potential control circuit 250 of the second conductor 221 illustrated in FIG. 5, the RF signal may mainly pass through the first variable capacitor 270, and the pulsed voltage signal may mainly pass through the second variable capacitor 271 in the potential control circuit 250 of the second conductor 221. The potentials of the ring electrode 201 and the edge ring 202 may be adjusted by the impedance of the second variable capacitor 271. In this way, the potentials of the ring electrode 201 and the edge ring 202 are adjusted with respect to the potentials of the substrate electrode 200 and the substrate W illustrated in FIG. 3, and the plasma sheaths PS generated on the substrate W and the edge ring 202 may be brought close to the horizontal. As a result, ions of the plasma may be supplied perpendicularly to the substrate W in the vicinity of an outer peripheral portion of the substrate W. Therefore, a state where a tilt angle (incidence angle of the ion with respect to the substrate W) is 90° may be maintained.

The control of executing the step ST1 and the step ST2, the control of executing the step ST3 and the step ST4, and the control of executing the step ST5 and the step ST6 may be continuously performed in any order.

According to the present exemplary embodiment, the plasma processing apparatus 1 includes the ring electrode 201 disposed in the electrostatic chuck 1111 and electrically connected to the conductive base 1110 via the second conductor 221, and the potential control circuit 250 electrically connected to the second conductor 221 between the ring electrode 201 and the conductive base 1110, in which the potential control circuit 250 includes at least one variable impedance element 251. Accordingly, the potential of the edge ring 202 can be suitably adjusted by changing the impedance of the variable impedance element 251 of the potential control circuit 250 to adjust the potential of the ring electrode 201. As a result, the potential of the edge ring 202 is adjusted according to the consumption amount of the edge ring 202, and the plasma sheaths PS generated on the substrate W and the edge ring 202 can be maintained horizontally. Therefore, it is possible to maintain a state where the tilt angle (incidence angle of the ion with respect to the substrate W) is 90° can be maintained in the vicinity of the outer peripheral portion of the substrate W.

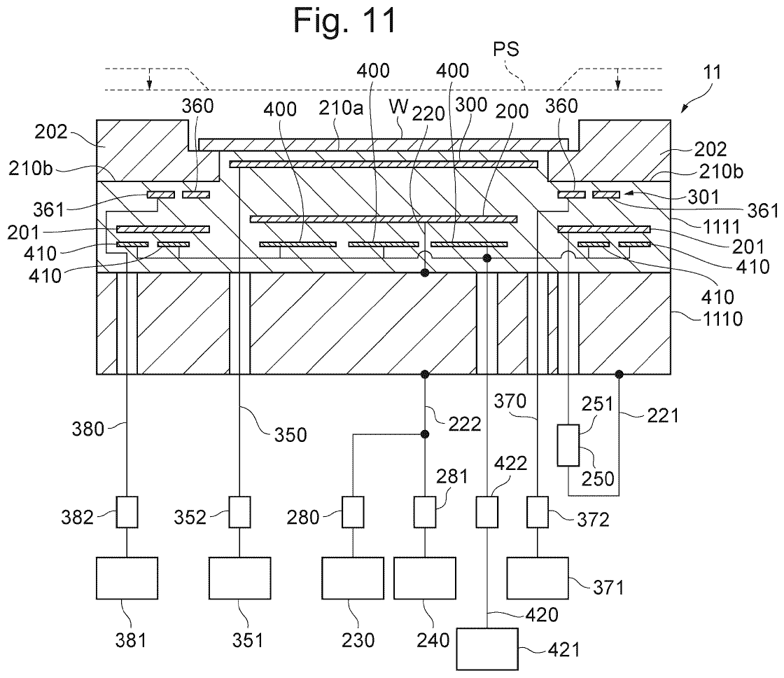

In the above-described embodiment, as illustrated in FIG. 11, the substrate support 11 may include at least one substrate heating element 400. The substrate heating element 400 may be disposed below the substrate electrode 200 in the electrostatic chuck 1111. In addition, the substrate support 11 may include at least one ring heating element 410. The ring heating element 410 may be disposed below the ring electrode 201 in the electrostatic chuck 1111. The substrate heating element 400 may include a plurality of substrate heating elements arranged in a horizontal direction. The ring heating element 410 may include a plurality of ring heating elements arranged in the horizontal direction.

The substrate heating element 400 and the ring heating element 410 may be connected to a heating element power supply 421 via a seventh conductor 420. At least one filter 422 of the RF filter and the voltage pulse filter may be electrically connected to the seventh conductor 420. The seventh conductor 420 may be electrically insulated from the conductive base 1110.

The variable impedance element 251 of the potential control circuit 250 described in the above-described embodiment may include at least one selected from a variable capacitor, a variable resistor, and a variable inductor.

The above-described embodiment is the capacitively coupled plasma processing apparatus, but is not limited thereto, and may be applied to other plasma processing apparatuses. For example, an inductively coupled plasma processing apparatus may be used instead of the capacitively coupled plasma processing apparatus.

The embodiments of the present disclosure further include the following aspects.

### (Addendum 1)

A plasma processing apparatus including:
a chamber;
a substrate support disposed in the chamber, the substrate support including
   a conductive base,
   an electrostatic chuck disposed on the conductive base and having a substrate support surface and a ring support surface,
   a substrate electrode disposed below the substrate support surface in the electrostatic chuck and electrically connected to the conductive base via a first conductor,
   a ring electrode disposed below the ring support surface in the electrostatic chuck and electrically connected to the conductive base via a second conductor, and
   an edge ring disposed on the ring support surface to surround a substrate disposed on the substrate support surface;
an RF generator electrically connected to the conductive base and configured to generate an RF signal;
a voltage pulse generator electrically connected to the conductive base and configured to generate a pulsed voltage signal; and
a potential control circuit electrically connected to the second conductor between the ring electrode and the conductive base, the potential control circuit including at least one variable impedance element.

### (Addendum 2)

The plasma processing apparatus according to Addendum 1,
in which the substrate support is configured such that a height of an upper surface of the edge ring is higher than a height of an upper surface of the substrate disposed on the substrate support surface.

### (Addendum 3)

The plasma processing apparatus according to Addendum 1 or 2,
in which the substrate support includes at least one substrate chuck electrode, and
the at least one substrate chuck electrode is disposed between the substrate electrode and the substrate support surface in the electrostatic chuck.

### (Addendum 4)

The plasma processing apparatus according to any one of Addenda 1 to 3,
in which the substrate support includes at least one ring chuck electrode, and
the at least one ring chuck electrode is disposed between the ring electrode and the ring support surface in the electrostatic chuck.

### (Addendum 5)

The plasma processing apparatus according to any one of Addenda 1 to 4,
in which the substrate support includes at least one substrate heating element, and
the at least one substrate heating element is disposed below the substrate electrode in the electrostatic chuck.

### (Addendum 6)

The plasma processing apparatus according to Addendum 5,
in which the at least one substrate heating element includes a plurality of substrate heating elements arranged in a horizontal direction.

### (Addendum 7)

The plasma processing apparatus according to any one of Addenda 1 to 6,
in which the substrate support includes at least one ring heating element, and
the at least one ring heating element is disposed below the ring electrode in the electrostatic chuck.

### (Addendum 8)

The plasma processing apparatus according to Addendum 7,
in which the at least one ring heating element includes a plurality of ring heating elements arranged in a horizontal direction.

### (Addendum 9)

The plasma processing apparatus according to any one of Addenda 1 to 8, further including:
an RF filter electrically connected between the voltage pulse generator and the conductive base; and
a voltage pulse filter electrically connected between the RF generator and the conductive base.

### (Addendum 10)

The plasma processing apparatus according to any one of Addenda 1 to 9, further including:
a controller configured to adjust the at least one variable impedance element based on a consumption amount of the edge ring.

### (Addendum 11)

The plasma processing apparatus according to Addendum 10,
in which the consumption amount of the edge ring is determined based on an operation time of the RF generator.

### (Addendum 12)

The plasma processing apparatus according to any one of Addenda 1 to 11,
in which the at least one variable impedance element includes first and second variable capacitors connected to each other in parallel,
the first variable capacitor is configured to control the RF signal supplied to the ring electrode, and
the second variable capacitor is configured to control the pulsed voltage signal applied to the ring electrode.

### (Addendum 13)

The plasma processing apparatus according to Addendum 12,
in which the potential control circuit includes a filter connected in parallel with the second variable capacitor.

### (Addendum 14)

The plasma processing apparatus according to Addendum 12 or 13, further including:
a controller,
in which the controller is configured to execute
   (a) adjusting the first variable capacitor, and
   (b) executing a first process after the (a), and
in the (b), the RF signal has a first power level higher than a zero power level, and the pulsed voltage signal has a zero voltage level.

### (Addendum 15)

The plasma processing apparatus according to any one of Addenda 12 to 14,
in which the controller is configured to execute
   (c) adjusting the second variable capacitor, and
   (d) executing a second process after the (c), and
in the (d), the RF signal has the zero power level, and the pulsed voltage signal has a first voltage level higher than the zero voltage level.

### (Addendum 16)

The plasma processing apparatus according to Addendum 15,
in which the first voltage level has a negative polarity.

### (Addendum 17)

The plasma processing apparatus according to any one of Addenda 12 to 16,
in which the controller is configured to execute
   (e) adjusting the second variable capacitor, and
   (f) executing a third process after the (e), and
in the (f), the RF signal has the first power level or a second power level different from the first power level, and the pulsed voltage signal has the first voltage level or a second voltage level different from the first voltage level.

### (Addendum 18)

A plasma processing apparatus including:
a chamber;
a substrate support disposed in the chamber, the substrate support including
   a conductive base,
   an electrostatic chuck disposed on the conductive base and having a substrate support surface and a ring support surface,
   a substrate electrode disposed below the substrate support surface in the electrostatic chuck and electrically connected to the conductive base via a first conductor,
   a ring electrode disposed below the ring support surface in the electrostatic chuck and electrically connected to the conductive base via a second conductor, and
   an edge ring disposed on the ring support surface to surround a substrate disposed on the substrate support surface;
at least one power supply electrically connected to the conductive base; and
a potential control circuit electrically connected to the second conductor between the ring electrode and the conductive base, the potential control circuit including at least one variable impedance element.

Each of the above-described embodiments is described for the purpose of description, and it is not intended to limit the scope of the present disclosure. Each of the above-described embodiments may be modified in various ways without departing from the scope and gist of the present disclosure. For example, some configuration elements in one embodiment may be added to other embodiments. In addition, some configuration elements in one embodiment can be replaced with corresponding configuration elements in another embodiment.

According to one exemplary embodiment of the present disclosure, it is possible to provide a technique capable of suitably adjusting a potential of an edge ring.

What is claimed is:

1. A plasma processing apparatus comprising:
a chamber;
a substrate support disposed in the chamber, the substrate support including:
a conductive base,
an electrostatic chuck disposed on the conductive base and having a substrate support surface and a ring support surface,
a substrate electrode disposed below the substrate support surface in the electrostatic chuck and electrically connected to the conductive base via a first conductor,
a ring electrode disposed below the ring support surface in the electrostatic chuck and electrically connected to the conductive base via a second conductor, and
an edge ring disposed on the ring support surface to surround a substrate disposed on the substrate support surface;
an RF generator electrically connected to the conductive base and configured to generate an RF signal;
a voltage pulse generator electrically connected to the conductive base and configured to generate a pulsed voltage signal; and
a potential control circuit electrically connected to the second conductor between the ring electrode and the conductive base, the potential control circuit including at least one variable impedance element.

2. The plasma processing apparatus according to claim 1,
wherein the substrate support is configured such that a height of an upper surface of the edge ring is higher than a height of an upper surface of the substrate disposed on the substrate support surface.

3. The plasma processing apparatus according to claim 1,
wherein the substrate support includes at least one substrate chuck electrode, and
the at least one substrate chuck electrode is disposed between the substrate electrode and the substrate support surface in the electrostatic chuck.

4. The plasma processing apparatus according to claim 3,
wherein the substrate support includes at least one ring chuck electrode, and
the at least one ring chuck electrode is disposed between the ring electrode and the ring support surface in the electrostatic chuck.

5. The plasma processing apparatus according to claim 4,
wherein the substrate support includes at least one substrate heating element, and
the at least one substrate heating element is disposed below the substrate electrode in the electrostatic chuck.

6. The plasma processing apparatus according to claim 5,
wherein the at least one substrate heating element includes a plurality of substrate heating elements arranged in a horizontal direction.

7. The plasma processing apparatus according to claim 5,
wherein the substrate support includes at least one ring heating element, and
the at least one ring heating element is disposed below the ring electrode in the electrostatic chuck.

8. The plasma processing apparatus according to claim 7,
wherein the at least one ring heating element includes a plurality of ring heating elements arranged in a horizontal direction.

9. The plasma processing apparatus according to claim 7, further comprising:
an RF filter electrically connected between the voltage pulse generator and the conductive base; and
a voltage pulse filter electrically connected between the RF generator and the conductive base.

10. The plasma processing apparatus according to claim 1, further comprising:
a controller configured to adjust the at least one variable impedance element based on a consumption amount of the edge ring.

11. The plasma processing apparatus according to claim 10,
wherein the consumption amount of the edge ring is determined based on an operation time of the RF generator.

12. The plasma processing apparatus according to claim 1,
wherein the at least one variable impedance element includes first and second variable capacitors connected to each other in parallel,
the first variable capacitor is configured to control the RF signal supplied to the ring electrode, and
the second variable capacitor is configured to control the pulsed voltage signal applied to the ring electrode.

13. The plasma processing apparatus according to claim 12,
wherein the potential control circuit includes a filter connected in parallel with the second variable capacitor.

14. The plasma processing apparatus according to claim 12, further comprising:
a controller,
wherein the controller is configured to execute:
(a) adjusting the first variable capacitor, and
(b) executing a first process after the (a), and
in the (b), the RF signal has a first power level higher than a zero power level, and the pulsed voltage signal has a zero voltage level.

15. The plasma processing apparatus according to claim 14,
wherein the controller is configured to execute:
(c) adjusting the second variable capacitor, and
(d) executing a second process after the (c), and
in the (d), the RF signal has the zero power level, and the pulsed voltage signal has a first voltage level higher than the zero voltage level.

16. The plasma processing apparatus according to claim 15,
wherein the first voltage level has a negative polarity.

17. The plasma processing apparatus according to claim 15,
wherein the controller is configured to execute:
(e) adjusting the second variable capacitor, and
(f) executing a third process after the (e), and
in the (f), the RF signal has the first power level or a second power level different from the first power level, and the pulsed voltage signal has the first voltage level or a second voltage level different from the first voltage level.

18. A plasma processing apparatus comprising:
a chamber;
a substrate support disposed in the chamber, the substrate support including:
a conductive base,
an electrostatic chuck disposed on the conductive base and having a substrate support surface and a ring support surface,
a substrate electrode disposed below the substrate support surface in the electrostatic chuck and electrically connected to the conductive base via a first conductor,
a ring electrode disposed below the ring support surface in the electrostatic chuck and electrically connected to the conductive base via a second conductor, and
an edge ring disposed on the ring support surface to surround a substrate disposed on the substrate support surface;
at least one power supply electrically connected to the conductive base; and
a potential control circuit electrically connected to the second conductor between the ring electrode and the conductive base, the potential control circuit including at least one variable impedance element.
